(19) United States
(12) Patent Application Publication
(10) Pub. No.: US 2025/0004107 A1
(43) Pub. Date: Jan. 2, 2025

(54) SENSOR PACKAGE AND METHOD OF MANUFACTURING A SENSOR PACKAGE

(71) Applicant: ams-OSRAM Asia Pacific Pte. Ltd., SINGAPORE (SG)

(72) Inventors: Tiao ZHOU, FRISCO, TX (US); Klaus SCHMIDEGG, GLEISDORF (AT); Harald ETSCHMAIER, GRAZ (AT)

(21) Appl. No.: 18/290,661

(22) PCT Filed: Jul. 20, 2022
(86) PCT No.: PCT/SG2022/050515

§ 371 Date: Jan. 19, 2024

Related U.S. Application Data
(60) Provisional application No. 63/225,042, filed on Jul. 23, 2021.

(30) Foreign Application Priority Data
Jul. 28, 2021 (DE) 10 2021 119 649.3

(51) Int. Cl. G01S 7/481; G01S 17/04; H01L 31/02; H01L 31/0203; H01L 31/173; H01L 31/18

(52) U.S. Cl. CPC G01S 7/4813; G01S 17/04; H01L 31/02005; H01L 31/0203; H01L 31/173; H01L 31/18

(57) ABSTRACT

A sensor package includes an encapsulation body formed from a mold compound having a front side and a back side opposite the front side, an optical sensor die embedded within the encapsulation body on the front side such that an active surface of the optical sensor die is uncovered by the encapsulation body, and a conductive via that extends from the front side to the back side through the encapsulation body. The sensor package also includes a topside redistribution layer arranged on the front side, the topside redistribution layer electrically connecting the optical sensor die to the conductive via, a connection element arranged on the back side for electrically connecting the sensor package to an integrated circuit device, and a backside redistribution layer arranged on the back side. The backside redistribution layer electrically connects the connection element to the conductive via.

The present disclosure relates to a sensor package and to a method of manufacturing a sensor package.

Optical sensors find applications in various modern electronic devices such as smartphones, tablet computers, laptops and wearables such as smartwatches. The optical sensors in these applications are typically employed for detecting ambient lighting conditions or for proximity sensing and gesture detection purposes. One of the major selling propositions for sensor packages in the abovementioned applications is a small size since space particularly in smartphones and wearable gadgets is very limited. A further challenge is the efficient prevention of cross talk for sensor packages that include an optical emitter and sensor for proximity sensing, for instance. Moreover, state-of-the-art devices typically include a clear mold structure for protection of the active components that, however, typically leads to performance and reliability degradation due to moisture absorption and permeation of the mold compound in addition to insufficiencies due to defects such as voids within the clear mold. To date, no solution is presented that addresses all of these challenges.

It is an object to provide an improved concept of a sensor package, which overcomes the limitations of present-day solutions and addresses the abovementioned challenges.

This object is achieved by the subject-matter of the independent claims. Further developments and embodiments are described in the dependent claims.

The improved concept is based on the idea of embedding an optical sensor die within a non-transparent molding compound in a manner such that only the active surface of the optical sensor die, e.g. the light capturing surface of a photodiode, is uncovered by the molding compound. In addition, a sensor package according to the improved concept features backside contacts that are electrically connected to the optical sensor die by means of vias and redistribution layers. The benefits of the improved concept are a reduced package size, in particular package height, in addition to the efficient prevention of cross-talk and other disadvantages of present-day solutions that employ a clear, i.e. transparent, molding compound.

Specifically, a sensor package according to the improved concept comprises an encapsulation body formed from a mold compound having a front side and a back side opposite the front side, and an optical sensor die that is embedded within the encapsulation body on the front side such that an active surface of the optical sensor die is uncovered by the encapsulation body. The sensor package further comprises a conductive via that extends from the front side through the encapsulation body to the back side, a topside redistribution layer arranged on the front side, the topside redistribution layer electrically connecting the optical sensor die to the conductive via, a connection element arranged on the back side for electrically connecting the sensor package to an integrated circuit device, and a backside redistribution layer arranged on the back side, the backside redistribution layer electrically connecting the connection element to the conductive via.

The encapsulation body is a mold compound, which can be a polymer mold compound, in particular formed from an epoxy. The optical sensor die is embedded in this encapsulation body in a manner such that an active surface, e.g. the light capturing surface of a photodiode, is uncovered by the encapsulation body and is hence exposed to an environment of the sensor package. In other words, the active surface of the optical sensor die terminates flush with a top surface of the encapsulation body, forming a common surface. In particular, the sensor package can be free of any further substrate such as a silicon chip or a laminate. In other words, the encapsulation body formed from the mold compound acts as a substrate of the sensor package. The optical sensor die can be encapsulated completely except for the active surface. Alternatively, a back side of the optical sensor die opposite the active surface can be uncovered by the encapsulation body. In other words, a thickness of the encapsulation body can correspond to a thickness of the optical sensor die.

The optical sensor die is for example a photodiode die, wherein a photodiode can be arranged on a substrate, e.g. a silicon chip, of the optical sensor die. Photodiodes are common components for converting captured photons into an electronic signal and are not further discussed throughout this disclosure.

The conductive via is a through-substrate via, or through-encapsulation via, for example, that extends through the encapsulation body. The conductive via is formed from a conductive material such as a metal. On the front side of the encapsulation body, i.e. the surface of the encapsulation body that comprises the uncovered active surface of the optical sensor die, a topside redistribution layer is arranged for electrically interconnecting the conductive via and a terminal of the optical sensor die.

Similarly, a backside redistribution layer is arranged on a back side of the encapsulation body, wherein the backside is opposite the front side. The backside redistribution layer is arranged for electrically interconnecting the conductive via and a connection element of the sensor package, e.g. a solder pad or a lead, which is likewise arranged on a backside of the encapsulation body. The topside redistribution layer and the backside redistribution layer are formed from a conductive material such as a metal. Likewise, the connection element is formed from a conductive material such as a metal. The connection element provides means to fixate and electrically connect the sensor package to an integrated circuit, e.g. to a PCB or a CMOS integrated circuit body, or to a socket that is electrically connected to an integrated circuit.

In some embodiments, the encapsulation body, the conductive via, the topside redistribution layer, the backside redistribution layer and the connection element form a land grid array, LGA, package.

A land grid array is a type of surface-mount packaging for integrated circuits having a rectangular grid of contacts on the back side of a package. The contacts can either be made by using an LGA socket, or by using solder paste, for instance. The LGA package can comprise pads that have a solderable surface finish for interconnecting to a printed circuit board with solder, for instance. Said LGA pads can be solder-mask defined (SMD) pads, which lower the risk of the pads being peeled off.

Alternatively, the sensor package can be based on a ball-grid array technology, e.g. an embedded wafer level ball grid array, eWLB, or on a pin-grid array, PGA, technology. Accordingly, the connection element can be a lead or a contact pad, in particular a solder pad.

In some embodiments, the mold compound is non-conductive.

In order to electrically isolate the optical sensor die particularly if the sensor package comprises further sensor dice or light-emitting dice, the mold-compound is a non-conductive material, e.g. a plastic or an epoxy.

In some embodiments, the mold body is opaque regarding an operation wavelength of the optical sensor die.

In order to optically isolate the optical sensor die particularly from optional further sensor dice or light-emitting dice, the mold-compound is a non-transparent material, e.g. a plastic or an epoxy. Opaque or non-transparent in this context refers to an operational wavelength of the optical sensor, e.g. a wavelength or wavelength range in the visible and/or infrared domain. This way, edges and sidewalls of the optical sensor die are fully encapsulated, which significantly reduces the risk of IR leakage, for example, and further protects the die from mechanical damage.

In particular, the sensor package is free of a clear, i.e. transparent, mold that is typically employed in conventional optical sensor packages that, together with a substrate portion, fully encapsulate the optical sensor.

In some embodiments, a thickness of the sensor package is equal to or less than 0.5 mm, in particular equal to or less than 0.25 mm.

Being free of a clear mold structure and a typically employed capping structure on top of said mold allows for a sensor package according to the improved concept to be of significantly smaller dimension compared to conventional sensor packages. In particular in terms of thickness, the size of the sensor package can be significantly reduced by a factor of two compared to present-day solutions, while at the same time efficiently preventing cross-talk and unwanted inefficiencies caused by a clear mold.

In some embodiments, the sensor package further comprises a topside dielectric layer arranged on the front side and encapsulating the topside redistribution layer.

A topside dielectric layer that, together with the mold compound, fully encapsulates the topside redistribution layer prevents short circuits between the topside redistribution layer and the optical sensor die, for instance. Furthermore, the topside dielectric layer can act as a passivation layer for protecting and passivating the topside redistribution layer. For example, the dielectric layer is formed from an oxide or nitride, such as silicon dioxide or silicon nitride. The dielectric layer may be also formed from an organic material, such as polyimide, BCB (Benzocyclobutane), PBO (Polybenzoxazoles), or silicone.

In some embodiments, the topside dielectric layer is opaque regarding an operation wavelength of the optical sensor die.

The topside dielectric layer may have optical properties such that infrared light is blocked, for example, and hence the leakage of light at the edge of the optical sensor die is prevented.

Alternatively, the topside dielectric layer is transparent regarding an operation wavelength of the optical sensor die. In these embodiments, the topside dielectric layer can further cover the active surface of the optical sensor die and be configured to act as a filter, a diffusor or a lens element for light captured by the optical sensor die.

In some embodiments, the sensor package further comprises an optical element, in particular an optical filter or a lens, arranged on the active surface of the optical sensor die.

Such optical elements can be employed to further engineer a capturing range of light of the optical sensor die. For example, incoming light can be passed through to the optical sensor die only if incoming at a specific wavelength range or angle of incidence.

In some embodiments, a back side of the optical sensor die is uncovered by the encapsulation body.

In order to further reduce a thickness of the sensor package, the encapsulation body can have a thickness that corresponds to that of the sensor die. In other words, both the active surface and a bottom side of the sensor die opposite the active surface can be uncovered by the encapsulation body such that only side surfaces of the optical sensor die are covered by the encapsulation body. This way, also further electrical connections can be realized via backside contacts of the optical sensor die, for instance.

In some further embodiments, the back side of the optical sensor die is covered by a dielectric layer.

If the backside of the optical sensor die is exposed, however, electrically contacting the backside is not desired, a dielectric layer can be arranged on the back side of the sensor package for electrically isolating and protecting the back side of the optical sensor die.

In some embodiments, the sensor package further comprises an optical emitter die embedded within the encapsulation body on the front side such that an emission surface of the optical emitter die is uncovered by the encapsulation body, wherein the optical emitter die and the optical sensor die are separated by a portion of the mold compound.

For example, the sensor package realizes a proximity sensor device, in which light is emitted by a light emitter and recaptured by the optical sensor die after being reflected off of a target object or target surface. To this end, the sensor package can further comprise an optical emitter die that is embedded within the encapsulation body in an analogous manner as the optical sensor die. Therein, the optical emitter die is arranged in proximity to the optical sensor die in a manner that the active surface of the optical sensor die and an emission surface of the emitter die are uncovered by the encapsulation body. In other words, the active surface of the optical sensor die, the emission surface of the emitter die and the front side of the encapsulation body terminate flush and form a common surface. The emitter die can comprise an optical emitter such as a VCSEL or an LED.

For optical and electrical isolation, the optical sensor die and the emitter die are arranged such that a portion of the encapsulation body separates said two dice. In particular, there is no direct light path between the active surface and the emission surface that does not pass through the mold compound.

In some further embodiments, the sensor package further comprises a further conductive via that extends from the front side through the encapsulation body to the back side, a further topside redistribution layer arranged on the front side, the further topside redistribution layer electrically connecting the optical emitter die to the further conductive via, a further connection element arranged on the back side for electrically connecting the sensor package to an integrated circuit device, and a further backside redistribution layer arranged on the back side, the further backside redistribution layer electrically connecting the further connection element to the further conductive via.

The function of said components is analogous to those discussed above and are configured to electrically interconnect the optical emitter die to the further connection elements on a back side of the encapsulation body. In some further embodiments, a back side of the optical emitter die is uncovered by the encapsulation body.

If both the emission surface and a bottom side of the emitter die opposite the active surface are uncovered by the encapsulation body such that only side surfaces of the emitter die are covered by the encapsulation body, electrical connections of backside contacts of the emitter die can be realized, for instance.

In some embodiments, the sensor package further comprises a conductive blind via that extends from the back side through the encapsulation body to a backside contact of the optical emitter die.

In such embodiments, a blind via is formed from the back side of the encapsulation body in order to expose the back side of the emitter die. Consequently, said blind via is filled with a conductive material, e.g. a metal, for electrically connecting terminals of the emitter die to the further backside redistribution layer and/or the further connection element.

In some embodiments, the sensor package further comprises an electrical interconnection between the optical sensor die and the optical emitter die. This way, an automatic laser shutdown safety mechanism can be realized, e.g. for eye safety purposes.

The aforementioned object is further solved by a method of manufacturing a sensor package. Said method comprises forming an encapsulation body from a mold compound, the encapsulation body having a front side and a back side opposite the front side, embedding an optical sensor die within the encapsulation body on the front side such that an active surface of the optical sensor die is uncovered by the encapsulation body, and forming a conductive via that extends from the front side through the encapsulation body to the back side.

The method further comprises arranging a topside redistribution layer on the front side, the topside redistribution layer electrically connecting the optical sensor die to the conductive via, arranging a connection element on the back side for electrically connecting the sensor package to an integrated circuit device, and arranging a backside redistribution layer on the back side, the backside redistribution layer electrically connecting the connection element to the conductive via.

Further embodiments of the manufacturing method according to the improved concept become apparent to a person skilled in the art from the embodiments of the semiconductor sensor device described above.

The following description of figures of exemplary embodiments may further illustrate and explain aspects of the improved concept. Components and parts with the same structure and the same effect, respectively, appear with equivalent reference symbols. Insofar as components and parts correspond to one another in terms of their function in different figures, the description thereof is not necessarily repeated for each of the following figures.

In the figures:

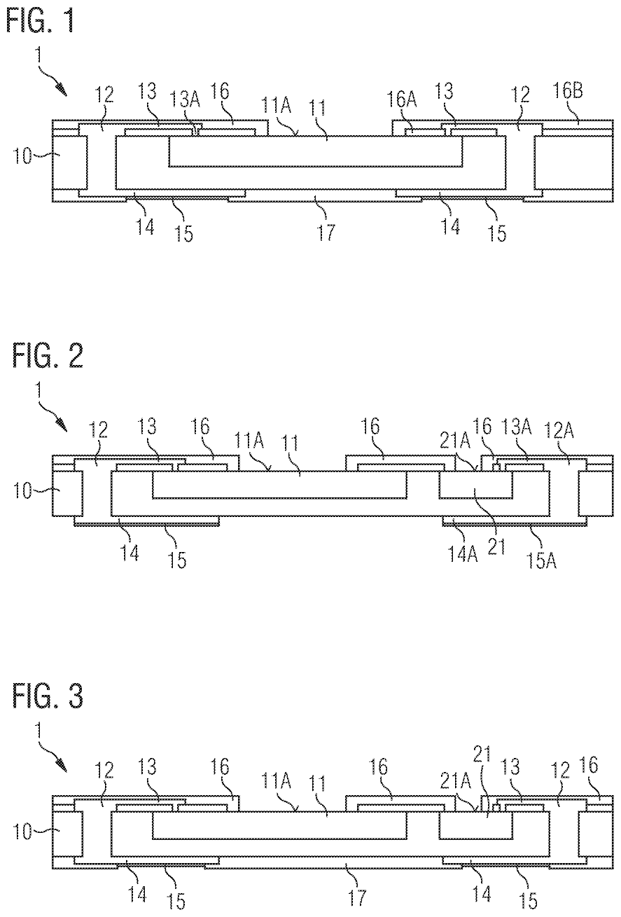

FIGS. 1 to 7 show exemplary embodiments of a sensor package according to the improved concept;

FIG. 8 shows an exemplary sensor assembly comprising an embodiment of a sensor package; and

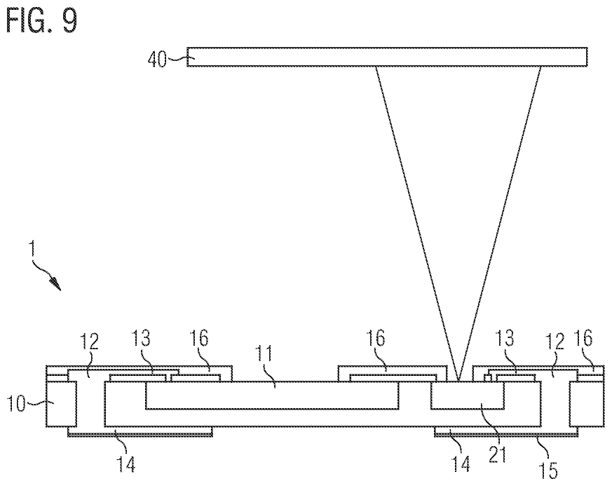

FIG. 9 shows an exemplary sensor device comprising an embodiment of a sensor package according to the improved concept.

FIG. 1 shows a cross-sectional schematic view of a first exemplary embodiment of a sensor package 1 according to the improved concept. The sensor package 1 comprises an encapsulation body 10, which is formed from a mold compound, e.g. a plastic or epoxy material. The encapsulation body 10 acts as a substrate body of the sensor package 1 and has a front side and a back side facing away from the front side. The front and back sides correspond to main extension planes of the encapsulation body 10.

The sensor package 1 further comprises an optical sensor die 11 that is embedded within the encapsulation body 10 in a manner such that an active surface 11A is uncovered by the encapsulation body 10. As illustrated, the active surface 11A and the front side of the encapsulation body 10 terminate flush and form a common surface, for instance. Alternatively, the active surface 11A can be arranged at a lower or larger height than the front side of the encapsulation body 10 with respect to the illustrated cross-sectional view. The optical sensor die 11 comprises an optical sensor such as a photodiode for capturing photons and converting a photon signal into an electronic readout signal. Thus, the active surface 11A can be a photon-capturing surface of a semiconductor, e.g. silicon-based, photodiode.

The sensor package 1 further comprises a conductive via 12 that extends through the encapsulation body 10 from the front side to the back side. The conductive via 12 is a through substrate via formed from a hole that is filled with a conductive material such as a metal, for instance. Moreover, a topside redistribution layer 13 electrically interconnects the optical sensor die 11, e.g. a terminal of the optical sensor, and the conductive via 12. Analogously, a backside redistribution layer 14 electrically interconnects a connection element 15, e.g. a contact pad such as a solder pad or a lead, and the conductive via 12. The topside and backside redistribution layers 13, 14 are electrically conductive and formed from a conductive material such as a metal. For example, a material of the redistribution layers 13, 14 corresponds to a material of the conductive via 12. Thus, the connection element 15 is electrically interconnected with the optical sensor die 11, e.g. with a terminal of an optical sensor of the optical sensor die 11.

The sensor package 1 further comprises a dielectric layer 16 covering and embedding the topside redistribution layer 13. In this embodiment, the dielectric layer 16 comprises a first sublayer 16A and a second sublayer 16B. The first sublayer 16A is arranged between the top surface and the topside redistribution layer 13 in a manner that merely the conductive via 12 as well as a small electric contact 13A are in direct electrical contact with the topside redistribution layer 13. The second sublayer 16B is arranged to cover the topside redistribution layer 13 and optionally fully covering the first sublayer 16A. The first and second sublayers 16A, 16B of the dielectric layer 16 can be formed from the same material or from different dielectric materials. For example, a material of the first and second sublayers 16A, 16B comprise an oxide, e.g. SiO2, and/or a nitride, e.g. SiN. The dielectric layer 16 acts as a protective passivation layer for the topside redistribution layer 13, the conductive via 12 and a terminal of the optical sensor die 11. Moreover, the dielectric layer 16 can have specific optical properties, e.g. the dielectric layer 16 blocks is opaque in the infrared domain and thus prevents light leaking to the photodiode at an edge of the optical sensor die 11, for instance.

The electric connection elements 15, e.g. solder pads, are formed on the backside of the encapsulation body 10 using a solder mask 17 formed from a polymer or a dielectric for defining the solder pads, for example. In other words, the connection elements 15 in this embodiment are solder-mask-defined, SMD, pads. Said solder mask 17 can remain on the finalized sensor package 1 for acting as a protective passivation layer analogous to the dielectric layer 16 on the top side. The electric connection elements 15 serve the purpose of providing terminals for operating and controlling the optical sensor of the optical sensor die 11 via an integrated circuit device, e.g. a PCB comprising active and passive circuitry, that is to be connected to the sensor package 1.

A thickness of the sensor package 1 is equal to or less than 0.5 mm, in particular equal to or less than 0.25 mm. This is achieved with the sensor package 1 being free of a transparent mold structure arranged on top of a substrate comprising the optical sensor die as typically realized in conventional sensor packages 1. Furthermore, the sensor package 1 according to the improved concept is free of a capping structure that is typically arranged distant from the top surface, e.g. on top of said clear mold structure. In contrast, the improved concept relies on an encapsulation body 10 that is non-transparent, i.e. opaque, with respect to an operating wavelength of the optical sensor die 11, and electrically non-conductive. Hence, the active surface 11A of the sensor die is exposed to an environment of the sensor package 1.

FIG. 2 shows a cross-sectional schematic view of a second exemplary embodiment of a sensor package 1 according to the improved concept. The embodiment comprises the features of the first embodiment and furthermore an optical emitter die 21. The optical emitter die 21 like the optical sensor die 11 is embedded within the encapsulation body 10 in a manner such that an emission surface 21A is uncovered by the encapsulation body 10. As illustrated, the emission surface 21A, the active surface 11A and the front side of the encapsulation body 10 terminate flush and form a common surface, for instance. Alternatively, the emission surface 21A can be arranged at a lower or larger height than the front side of the encapsulation body 10 with respect to the illustrated cross-sectional view. The optical emitter die 21 comprises an optical emitter such as a VCSEL or an LED for emitting photons, e.g. at an operating wavelength of an optical sensor of the optical sensor die 11. For example, the emission wavelength of the optical emitter die 21 and an operating wavelength of the optical sensor die 11 correspond to a wavelength or wavelength range in the visible domain or in the infrared domain, e.g. comprising 840 nm or 930 nm. The emitter die 21 is embedded within the encapsulation body 10 such that at least a portion of the mold compound is arranged between the emitter die 21 and the optical sensor die 11, hence separating these components. In other words, the mold compound electrically isolates the optical sensor die 11 from the emitter die 21 and optically isolates particularly the active surface 11A of the optical sensor die 11 and the emission surface 21A of the emitter die 21. This way, no direct optical path is provided between the active surface 11A and the emission surface 21A that does not pass through the opaque encapsulation body 10. Furthermore, for preventing short circuits, the dielectric layer 16 covers a portion of the optical sensor die 10, a portion of the emitter die 21 and the mold compound arranged in between. Alternatively, a topside redistribution layer can electrically interconnect a terminal of the optical sensor die 10 and a terminal of the emitter die 21, e.g. for realizing an interlock for eye safety purposes. Said topside redistribution layer can be covered by the dielectric layer acting as protective passivation.

Analogous to the configuration for the optical sensor die as described with respect to the first embodiment of FIG. 1, the emitter die 21 is likewise interconnected to a further conductive via 12A via a further topside redistribution layer 13A. Similarly, the further connection element 15A is electrically interconnected with the further conductive via 12A via a further backside redistribution layer 14A. Thus, the further connection element 15A is electrically interconnected with the emitter die 21, e.g. with a terminal of an optical emitter of the emitter die 21.

Furthermore, in this embodiment the connection element 15 and the further connection element 15A can be non-solder-mask defined, NSMD, pads.

Like the active surface 11A of the optical sensor die 11, the emission surface 21A of the emitter die 21 is exposed to the environment of the sensor package 1. In particular, no clear mold covers the surface of the emission surface 21A.

FIG. 3 shows a third embodiment of a sensor package 1 according to the improved concept. This embodiment corresponds to the second embodiment but includes the solder-mask defined, SMD, pads of FIG. 1.

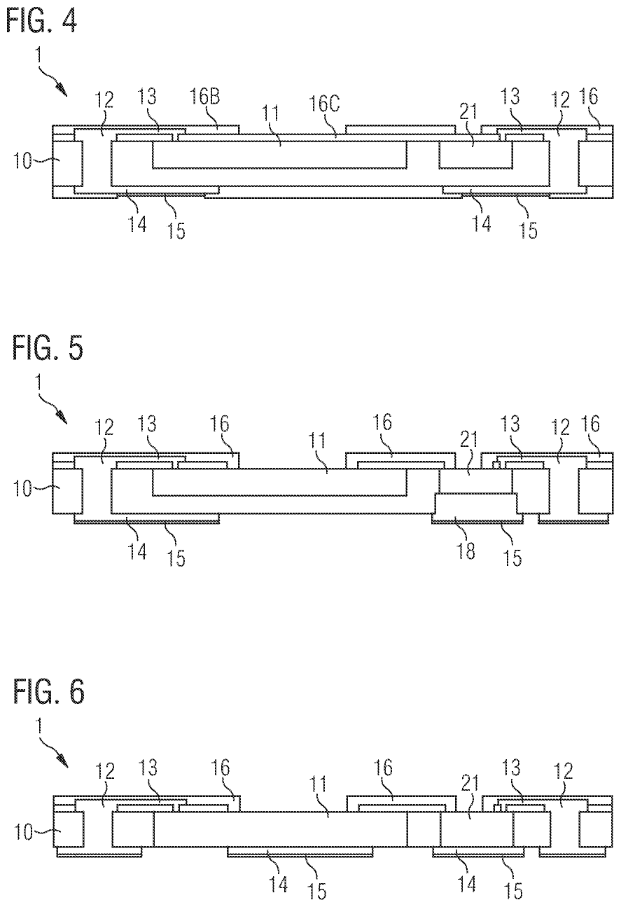

FIG. 4 shows a cross-sectional schematic view of a fourth embodiment of a sensor package 1. Compared to the embodiment of FIGS. 2 and 3, in this embodiment one of the sublayers 16A, 16B, e.g. in this case the first sublayer 16A, of the dielectric layer 16 covers the active surface 11A of the optical sensor die 11 and the emission surface 21A of the emitter die 21. Said sublayer 16A, 16B that covers the active surface 11A and the emission surface 21A is transparent with respect to an operating wavelength of the emitter and optical sensor and is configured to act not only as a passivation but in addition as an optical element 16C, which realizes a filter and/or diffusor or alternatively a lens element. Both sublayers 16A, 16B can be of the same material, i.e. being transparent or the sublayer that is not covering the active surface 11A, e.g. in this case the second sublayer 16B, is of an alternative material that is opaque.

The sublayer 16A, 16B can alternatively cover the active surface 11A of the optical sensor die 11 but the emission surface 21A remains uncovered, or vice versa. Likewise, both sublayers 16A, 16B can cover the active surface 11A of the optical sensor die 11 and/or the emission surface 21A of the emitter die 21.

The sublayers 16A, 16B covering the active surface 11A and/or the emission surface can be either blanket layer(s) or they are patterned, e.g. in cases in which the sensor comprises multiple photodiodes or channels, for realizing filters or diffusers that are selectively coated to different photodiodes of the optical sensor die 11.

FIG. 5 shows a cross-sectional schematic view of a fifth embodiment of a sensor package 1. The fifth embodiment is similar to the second embodiment of FIG. 2, however additionally takes into account the fact that particularly VCSEL emitters often comprise a back side electrical contact for operating the emitter. Thus, in this fifth embodiment, the back side contact of the emitter die 21 is electrically connected to the associated connection element 15 via a blind via 18 that extends from the back side of the encapsulation body to a back side of the emitter die 21.

The blind via 18, like the conductive through via 12, is filled or plated with a conductive material such as a metal for interconnecting the connection element 15 and a backside terminal the emitter die 21.

Alternatively, as illustrated in the sixth embodiment of FIG. 6, the encapsulation body 10 can be backside grinded such that at least the back side of the emitter die 21, like the emission surface 21A, is uncovered by the mold compound. Additionally, also a back side of the optical sensor die 11 can be exposed. In other words, as illustrated in FIG. 6, a thickness of the sensor die 11 and of the emitter die 21 can correspond to a thickness of the encapsulation body 10. Consequently, the backside redistribution layers 14 and connection elements 15 are arranged on the back side for contacting backside terminals of the emitter die 21, and optionally of the optical sensor die 11. This way, an overall thickness of the sensor package can be significantly reduced, e.g. to significantly smaller than 0.25 mm.

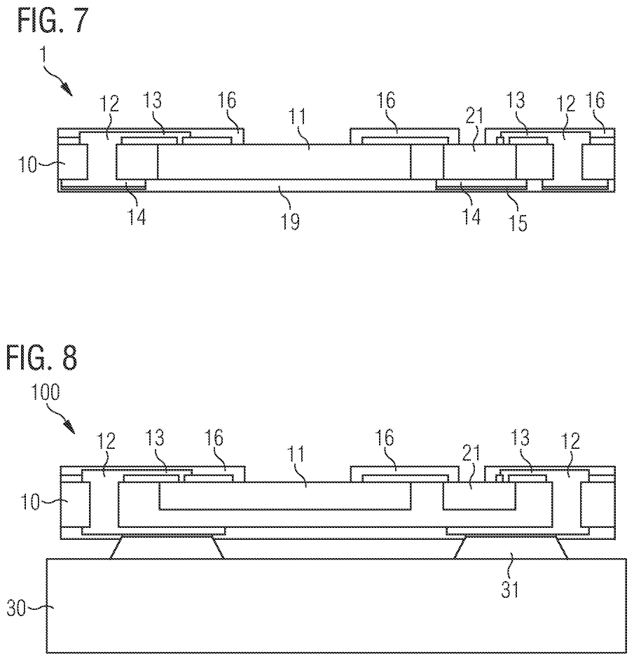

The seventh embodiment of FIG. 7 is similar to the fifth embodiment of FIG. 5 and additionally comprises a backside passivation layer 19 formed from a dielectric material. For example, a material of the backside passivation layer 19 corresponds to a material of the dielectric layer 16, which can either be a single-material layer or a layer formed from different sublayers 16A, 16B as described above.

FIG. 8 shows a cross-sectional schematic view of an exemplary sensor assembly 100 comprising an embodiment of a sensor package 1, e.g. the third embodiment of FIG. 3. For forming such a sensor assembly, a sensor package 1 is mounted on a circuit portion 30 via second level interconnects 31. The circuit portion 30 can be flexible or a PCB, for instance. Alternatively, the circuit portion can be a CMOS body comprising an integrated circuit. The second level interconnects 31 are electrically conductive and interconnect the connection elements 15 of the sensor package 1 to connection elements of the circuit portion 30, e.g. solder pads. Thus, the second level interconnects 31 can be formed by solder joints through a reflow process, or from conductive glue. As illustrated, after assembly the sensor die 11 and the emitter die 21 are exposed while all electrical interconnects to the circuit portion 30 are arranged at the backside of the sensor package 1.

FIG. 9 shows the working principle of a sensor package 1 implemented as a proximity sensor. Thus, the emitter die 21 comprises an optical emitter that is configured to emit light in a substantially orthogonal direction with respect to the emission surface 21A. The emitted light propagates towards an object 40, e.g. a human body part, and is reflected off of a surface of the object 40. The optical sensor die 11 comprises a photodiode that is sensitive in an emission wavelength of the emitter and is configured to detect at least a portion of the reflected light. From an emission signal and a detection signal, a proximity of the sensor package 1 to the object 40 can be determined, e.g. via a readout circuit that is connected to the connection elements 15.

To summarize, a sensor package 1 according to the improved concept due to its small form factor and particularly due to its small thickness, can be conveniently employed in wearable devices such as smartwatches or earphones for realizing a proximity sensor for determining whether the device is worn or not, for instance. However, a placement in a mobile phone or smartphone can be advantageous as well, as the typical bezel of a phone in this case can be significantly reduced in terms of the size. Due to the absence of a clear mold covering optical components, imperfections due to process defects in this clear mold as well as performance and reliability degradations of the optical emitter, e.g. a VCSEL, caused by moisture absorption and permeation within this clear mold are prevented. Furthermore, cross-talk is efficiently suppressed or even completely prevented without the need of an additional capping structure. In addition, the improved concept is free of wire bonding particularly on the front side.

It is further pointed out that a sensor package 1 according to the improved concept is not limited to applications for proximity sensing. The improved concept can likewise be implemented in all types of optical sensing devices having an emitter and receiver for efficiently reducing cross-talk while maintaining a small form factor, i.e. footprint and thickness. For example, an alternative application is a module for facial or fingerprint recognition, in which an illuminating light source, such as a dot projector acts as emitter and an image sensor is employed as photosensitive element. Further applications include ambient light sensing and gesture detection, for example.

The embodiments of the sensor package and the manufacturing method herein have been discussed for the purpose of familiarizing the reader with novel aspects of the idea. Although preferred embodiments have been shown and described, many changes, modifications, equivalents and substitutions of the disclosed concepts may be made by one having skill in the art without unnecessarily departing from the scope of the claims.

In particular, the disclosure is not limited to the disclosed embodiments, and gives examples of as many alternatives as possible for the features included in the embodiments discussed. However, it is intended that any modifications, equivalents and substitutions of the disclosed concepts be included within the scope of the claims which are appended hereto.

Features recited in separate dependent claims may be advantageously combined. Moreover, reference signs used in the claims are not limited to be construed as limiting the scope of the claims.

Furthermore, as used herein, the term “comprising” does not exclude other elements. In addition, as used herein, the article “a” is intended to include one or more than one component or element, and is not limited to be construed as meaning only one.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is in no way intended that any particular order be inferred.

This patent application claims the priority of German patent application 10 2021 119 649.3, the disclosure content of which is hereby incorporated by reference.

### REFERENCES

1 sensor package
10 encapsulation body
11 optical sensor die
11A active surface
12, 12A conductive via
13, 13A topside redistribution layer
14, 14A backside redistribution layer
15, 15A connection element
16 dielectric layer
16A, 16B sublayer
16C optical element
17 solder mask
18 blind via
19 passivation layer
21 emitter die
21A emission surface
30 circuit portion
31 interconnect
40 object
100 sensor assembly

1. A sensor package, comprising:
an encapsulation body formed from a mold compound having a front side and a back side opposite the front side;
an optical sensor die embedded within the encapsulation body on the front side such that an active surface of the optical sensor die is uncovered by the encapsulation body;
a conductive via that extends from the front side to the back side through the encapsulation body;
a topside redistribution layer arranged on the front side, the topside redistribution layer electrically connecting the optical sensor die to the conductive via;
a connection element arranged on the back side for electrically connecting the sensor package to an integrated circuit device;
a backside redistribution layer arranged on the back side, the backside redistribution layer electrically connecting the connection element to the conductive via;
an optical emitter die embedded within the encapsulation body on the front side such that an emission surface of the optical emitter die is uncovered by the encapsulation body, wherein the optical emitter die and the optical sensor die are separated by a portion of the mold compound; and
an electrical interconnection between the optical sensor die and the optical emitter die,
wherein a thickness of the sensor package is equal to or less than 0.5 mm.

2. The sensor package according to claim 1, wherein the encapsulation body, the conductive via, the topside redistribution layer, the backside redistribution layer and the connection element form a land grid array, LGA, package.

3. The sensor package according to claim 1, wherein the mold compound is non-conductive.

4. The sensor package according to claim 1, wherein the mold body is opaque regarding an operation wavelength of the optical sensor die.

5. The sensor package according to claim 1, wherein the connection element is a lead or a contact pad, in particular a solder pad.

6. The sensor package according to claim 1, wherein a thickness of the sensor package is equal to or less than 0.25 mm.

7. The sensor package according to claim 1, further comprising a topside dielectric layer arranged on the front side and encapsulating the topside redistribution layer.

8. The sensor package according to claim 7, wherein the topside dielectric layer is opaque regarding an operation wavelength of the optical sensor die.

9. The sensor package according to claim 1, further comprising an optical element, in particular an optical filter or a lens, arranged on the active surface of the optical sensor die.

10. The sensor package according to claim 1, wherein a back side of the optical sensor die is uncovered by the encapsulation body.

11. The sensor package according to claim 10, wherein the back side of the optical sensor die is covered by a dielectric layer.

12. (canceled)

13. The sensor package according to claim 1, further comprising:
a further conductive via that extends from the front side through the encapsulation body to the back side;
a further topside redistribution layer arranged on the front side, the further topside redistribution layer electrically connecting the optical emitter die to the further conductive via;
a further connection element arranged on the back side for electrically connecting the sensor package to an integrated circuit device; and
a further backside redistribution layer arranged on the back side, the further backside redistribution layer electrically connecting the further connection element to the further conductive via.

14. The sensor package according to claim 1, wherein a back side of the optical emitter die is uncovered by the encapsulation body.

15. The sensor package according to claim 1, further comprising a conductive blind via that extends from the back side through the encapsulation body to a backside contact of the optical emitter die.

16. (canceled)

17. A method of manufacturing a sensor package, the method comprising:
forming an encapsulation body from a mold compound, the encapsulation body having a front side and a back side opposite the front side;
embedding an optical sensor die within the encapsulation body on the front side such that an active surface of the optical sensor die is uncovered by the encapsulation body;
forming a conductive via that extends from the front side through the encapsulation body to the back side;
arranging a topside redistribution layer on the front side, the topside redistribution layer electrically connecting the optical sensor die to the conductive via;
arranging a connection element on the back side for electrically connecting the sensor package to an integrated circuit device;
arranging a backside redistribution layer on the back side, the backside redistribution layer electrically connecting the connection element to the conductive via;
embedding an optical emitter die within the encapsulation body on the front side such that an emission surface of the optical emitter die is uncovered by the encapsulation body, wherein the optical emitter die and the optical sensor die are separated by a portion of the mold compound; and
forming an electrical interconnection between the optical sensor die and the optical emitter die.
